(19) United States
(12) Patent Application Publication
(10) Pub. No.: US 2025/0271483 A1
(43) Pub. Date: Aug. 28, 2025

(54) ELECTROMAGNETIC WAVE TESTING DEVICE AND ELECTROMAGNETIC WAVE TESTING METHOD

(71) Applicant: TDK Corporation, Tokyo (JP)

(72) Inventors: Masataka MIDORI, Tokyo (JP); Hiroshi KURIHARA, Tokyo (JP); Tomohiro HONYA, Tokyo (JP)

(73) Assignee: TDK Corporation, Tokyo (JP)

(21) Appl. No.: 19/047,891

(22) Filed: Feb. 7, 2025

(30) Foreign Application Priority Data
Feb. 26, 2024 (JP) 2024-026135

(51) Int. Cl. G01R 29/10; G01R 29/08; G01R 31/00

(52) U.S. Cl. CPC G01R 29/105; G01R 29/0814; G01R 31/001

(57) ABSTRACT

An electromagnetic wave testing device including: a reverberation chamber; an antenna installed inside the reverberation chamber and emitting electromagnetic waves of frequencies below a resonant frequency of the reverberation chamber; a mounting stand of a flat plate shape having a mounting surface, which is a face including a first side and a second side facing the first side, made of a conductor on which the test object is placed; a first grounding part electrically connecting an object having a ground electric potential and the first side to each other; and a second grounding part electrically connecting the object and the second side to each other.

### BACKGROUND OF THE INVENTION

### Field of the Invention

The present disclosure relates to an electromagnetic wave testing device and an electromagnetic wave testing method.

Priority is claimed on Japanese Patent Application No. 2024-026135, filed Feb. 26, 2024, the content of which is incorporated herein by reference.

### Description of Related Art

Researches and developments are being conducted on electromagnetic wave testing devices that use a reverberation chamber to perform radiation immunity tests. A radiation immunity test is a test for checking whether or not an electronic device properly operates by applying a uniform electric field of which the strength is high to the electronic device installed inside a reverberation chamber as a test object. In this specification, an electric field may be rephrased as either a magnetic field or an electromagnetic field.

The reverberation chamber, for example, is configured using a cavity resonator made of metal, an antenna device that emits electromagnetic waves into the inside of the cavity resonator, and an electromagnetic stirrer that stirs the electromagnetic waves emitted from the antenna device. The reverberation chamber generates an electric field applied to a test object using a resonance phenomenon of electromagnetic waves inside the cavity resonator. Variations in strength due to the dimensions of the cavity resonator appear in the distribution of the strength of an electric field generated in this way. In other words, the distribution of the strength of the electric field generated by the cavity resonator becomes a non-uniform distribution. For this reason, the electromagnetic stirrer stirs electromagnetic waves inside the cavity resonator and causes the distribution of the strength of the electric field generated by the cavity resonator to approach a uniform distribution. In accordance with this, the reverberation chamber allows a user to be able to conduct a radiation immunity test with high test quality. In this specification, for the convenience of description, a method of conducting a radiation immunity test using a resonance phenomenon in a reverberation chamber in this way will be referred to as a reverberation chamber method.

In the reverberation chamber method, it is known that the resonant frequency of a cavity resonator is inversely proportional to the dimensions of the cavity resonator. For this reason, in a radiation immunity test according to the reverberation chamber method, the lower the frequency of the electric field generated inside a reverberation chamber using the resonance phenomenon, the larger the volume of the reverberation chamber needs to be.

On the other hand, in a radiation immunity test using an anechoic chamber instead of a reverberation chamber, electric fields of a low frequency band are applied to an electronic device inside the anechoic chamber. The low frequency band is a frequency band below a lowest usable frequency (LUF) at which a reverberation chamber functions, a frequency band below a lowest-order resonant frequency of the reverberation chamber (that is, a first resonant frequency), or the like. If a radiation immunity test using electric fields of such a low frequency band is to be conducted inside a reverberation chamber, a dimension of the reverberation chamber would be about 10 km. A reverberation chamber of such a dimension limits the flexibility of a place in which it is installed, which is not desirable. For this reason, in recent years, it has been preferable that a reverberation chamber include a device capable of performing a radiation immunity test using a low frequency band and have a size with which an electrical device can be inserted therein.

As a device capable of performing a radiation immunity test using a low frequency band inside a reverberation chamber, a device called a Transmission Line System (TLS) is known. As transmission line systems, a device applying an electric field from an antenna such as a transverse electro-magnetic (TEM) plate antenna or a strip line to an electronic device and the like are known. In this specification, for the convenience of description, a method of conducting a radiation immunity test using a transmission line system is referred to as a transmission line system method in description.

Here, as a mounting stand on which a test object that is a target for conducting a radiation immunity test using an anechoic chamber is placed, a mounting stand including: a top plate; leg parts provided on the bottom side of the top plate to support the top plate; a grounding plate provided on the surface of the top plate and made of a metal material; and a connecting arm member connecting the grounding plate to a wall-face metal plate of the anechoic chamber, in which a housing part extending from an inner portion to an outer edge portion and housing the connecting arm member to be movable forward and backward by opening the outer edge portion is disposed on the top plate, and the connecting arm member is configured using: an arm part connected to the grounding plate that extends along the housing part and is attached to be movable inside the housing part; and a connecting part disposed on a tip side of the arm part and protruding from the housing part to be connected to the wall-face metal plate of the anechoic chamber is known (see Patent Document 1).

### PATENT DOCUMENTS

[Patent Document 1] Japanese Unexamined Patent Application, First Publication No. 2010-127870

### SUMMARY OF THE INVENTION

However, a method of using a mounting stand as described in Patent Document 1 in a radiation immunity test using a low-frequency band inside a reverberation chamber was not established until now.

The present disclosure was made in consideration of such situations, and an objective thereof is to provide an electromagnetic wave testing device and an electromagnetic wave testing method that are capable of improving the uniformity of electric field strength of a grounded metallic mounting stand in a case in which a radiation immunity test using a low frequency band is conducted inside a reverberation chamber.

One aspect of the present disclosure is an electromagnetic wave testing device including: a reverberation chamber; an antenna installed inside the reverberation chamber and emitting electromagnetic waves of frequencies below a resonant frequency of the reverberation chamber; a mounting stand of a flat plate shape having a mounting surface, which is a face including a first side and a second side facing the first side, made of a conductor on which the test object is placed; a first grounding part electrically connecting an object having a ground electric potential and the first side to each other; and a second grounding part electrically connecting the object and the second side to each other.

In addition, one aspect of the present disclosure is an electromagnetic wave testing device including: a reverberation chamber; a mounting stand of a flat plate shape having a mounting surface, which is a face including a first side and a second side facing the first side, made of a conductor on which a test object is placed; a first grounding part electrically connecting an object having a ground electric potential and the first side to each other; and a second grounding part electrically connecting the object and the second side to each other, in which an antenna emitting electromagnetic waves of frequencies below a resonant frequency of the reverberation chamber is installed in the reverberation chamber.

Furthermore, one aspect of the present disclosure is an electromagnetic wave testing method using an electromagnetic wave testing device including: a reverberation chamber; an antenna installed inside the reverberation chamber and emitting electromagnetic waves of frequencies below a resonant frequency of the reverberation chamber; and a mounting stand of a flat plate shape having a mounting surface, which is a face including a first side and a second side facing the first side, made of a conductor on which a test object is placed, the electromagnetic wave testing method including: electrically connecting an object having a ground electric potential and the first side to each other using a first grounding part; and electrically connecting the object and the second side to each other using a second grounding part.

According to the present disclosure, the uniformity of electric field strength of a grounded metallic mounting stand can be improved in a case in which a radiation immunity test using a low frequency band is conducted inside a reverberation chamber.

### BRIEF DESCRIPTION OF THE DRAWINGS

FIG. 1 is a diagram illustrating an example of the configuration of an electromagnetic wave testing device 1 according to an embodiment.

FIG. 2 is an enlarged perspective view of a mounting stand 12 illustrated in FIG. 1.

FIG. 3 is an enlarged perspective view of the mounting stand 12 to which a second grounding part ST2 is connected together with a first grounding part ST1.

FIG. 4 is a diagram illustrating a frequency spectrum of electric field strength detected by an electric field sensor installed near the center of a mounting surface.

FIG. 5 is a diagram illustrating an example of a result of analysis of a distribution of electric field strength of 27.5 MHz inside a reverberation chamber 10 using a finite element method in a case in which the reverberation chamber 10, in which a mounting stand 12 is not installed, is seen in a negative direction of a Z axis.

FIG. 6 is a diagram illustrating an example of a result of analysis of a distribution of electric field strength of 27.5 MHz inside a reverberation chamber 10 using a finite element method in a case in which the reverberation chamber 10, in which the mounting stand 12 is not installed, is seen in a negative direction of a Y axis.

FIG. 7 is a diagram illustrating an example of a result of analysis of a distribution of electric field strength of 27.5 MHz inside a reverberation chamber 10 using a finite element method in a case in which the reverberation chamber 10, in which the mounting stand 12 to which a first grounding part ST1 is connected is installed as illustrated in FIG. 2, is seen in a negative direction of a Z axis.

FIG. 8 is a diagram illustrating an example of a result of analysis of a distribution of electric field strength of 27.5 MHz inside a reverberation chamber 10 using a finite element method in a case in which the reverberation chamber 10, in which the mounting stand 12 to which the first grounding part ST1 is connected is installed as illustrated in FIG. 2, is seen in a negative direction of the Y axis.

FIG. 9 is a diagram illustrating an example of a result of analysis of a distribution of electric field strength of 27.5 MHz inside a reverberation chamber 10 using a finite element method in a case in which the reverberation chamber 10, in which the mounting stand 12 to which the first grounding part ST1 and the second grounding part ST2 are connected is installed as illustrated in FIG. 3, is seen in a negative direction of the Z axis.

FIG. 10 is a diagram illustrating an example of a result of analysis of a distribution of electric field strength of 27.5 MHz inside a reverberation chamber 10 using a finite element method in a case in which the reverberation chamber 10, in which the mounting stand 12 to which the first grounding part ST1 and the second grounding part ST2 are connected is installed as illustrated in FIG. 3, is seen in a negative direction of the Y axis.

FIG. 11 is a diagram illustrating an example of a table comparing a measurement result of reference electric field strength with a measurement result of each of first electric field strength to third electric field strength.

FIG. 12 is a diagram illustrating an example of graphs in which frequency spectra illustrated in FIG. 11 are plotted.

FIG. 13 is a diagram illustrating an example of a table comparing a measurement result of reference electric field strength with a measurement result of each of fourth electric field strength to sixth electric field strength.

FIG. 14 is a diagram illustrating an example of graphs in which frequency spectra illustrated in FIG. 13 are plotted.

FIG. 15 is a diagram illustrating an example of a table comparing a measurement result of reference electric field strength with a measurement result of each of seventh electric field strength and eighth electric field strength.

FIG. 16 is a diagram illustrating an example of graphs in which frequency spectra illustrated in FIG. 15 are plotted.

### DETAILED DESCRIPTION OF THE INVENTION

### Embodiment

Hereinafter, an embodiment of the present disclosure will be described with reference to the drawings. Hereinafter, for the simplification of description, a case in which there is no electric potential difference or almost no electric potential difference between a plurality of members having a ground electric potential will be described. In the following description, an electric field may be rephrased as either a magnetic field or an electromagnetic field. Hereinafter, for the convenience of description, the strength of an electric field will be simply referred to as electric field strength in description. A three-dimensional coordinate system TC illustrated in some of a plurality of drawings referred to in this specification is a three-dimensional orthogonal coordinate system representing directions in each diagram. Hereinafter, for the convenience of description, an X axis in the three-dimensional coordinate system TC will be simply referred to as an X axis in description. In addition, hereinafter, for the convenience of description, a Y axis in the three-dimensional coordinate system TC will be simply referred to as a Y axis in description. Hereinafter, for the convenience of description, a Z axis in the three-dimensional coordinate system TC will be simply referred to as a Z axis in description. Hereinafter, in each drawing in which the three-dimensional coordinate system TC is drawn, a case in which a negative direction of the Z axis coincides with a vertical direction, that is, a direction of gravity will be described as an example. For this reason, hereinafter, for the convenience of description, a positive direction of the Z axis will be referred to as upward or an upward direction, and a negative direction of the Z axis will be referred to as downward or a downward direction in description.

### Configuration of Electromagnetic Wave Testing Device

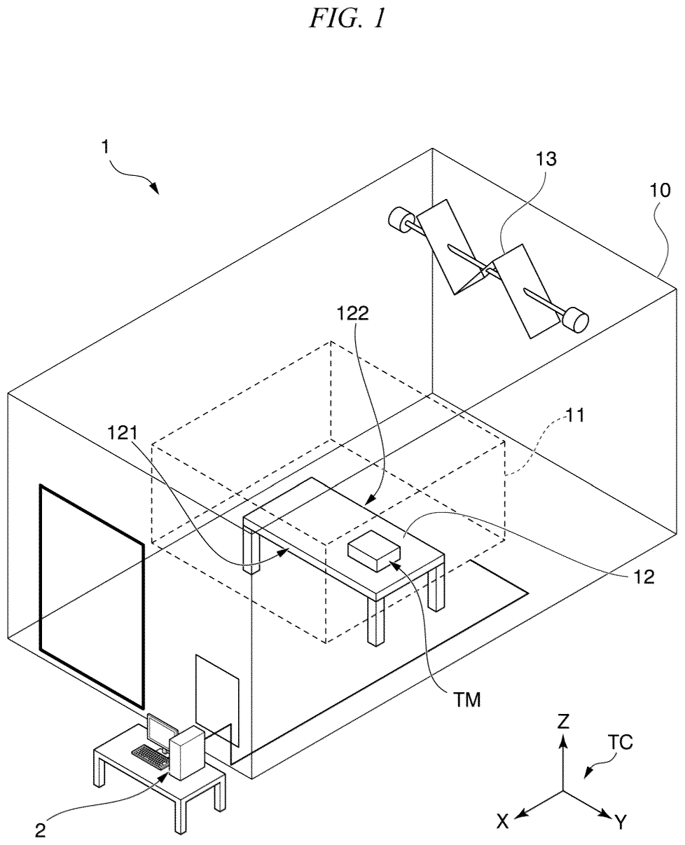

First, the configuration of an electromagnetic wave testing device 1 according to an embodiment will be described with reference to FIG. 1. FIG. 1 is a diagram illustrating an example of the configuration of the electromagnetic wave testing device 1 according to an embodiment.

The electromagnetic wave testing device 1 is a device that conducts a radiation immunity test on a test object TM using an electronic device that is a target for which the radiation immunity test is performed as the test object TM. A radiation immunity test is a test for checking whether or not a test object TM property operates by applying a uniform electric field of which strength is high to the test object TM. Hereinafter, as an example, a case in which the test object TM is an electronic device with a parallelepiped shape as a whole, as illustrated in FIG. 1 will be described. The electronic device that is a target for conducting a radiation immunity test as a test object TM may be any device as long as it is a device that is electrically controlled. For this reason, the test object TM is a device, which is electrically controlled, such as a multi-functional mobile phone terminal (smartphone), a mobile phone terminal, a drive recorder, any of various kinds of computers, or the like, but is not limited thereto.

The electromagnetic wave testing device 1 conducts a radiation immunity test using a hybrid method. The hybrid method is a method of conducting a radiation immunity test using a combination of a reverberation chamber method and a Transmission Line System (TLS) method. The reverberation chamber method is a method of conducting a radiation immunity test using a resonance phenomenon inside a reverberation chamber. The transmission line system method is a method of conducting a radiation immunity test using a transmission line system. The transmission line system is a device that applies an electric field from an antenna such as a Transverse Electro-Magnetic (TEM) plate antenna, a strip line, or the like to an electronic device.

The electromagnetic wave testing device 1 includes a reverberation chamber 10, an antenna 11, a mounting stand 12, and an electromagnetic stirrer 13. The electromagnetic wave testing device 1 may have a configuration not including the antenna 11. In such a case, an externally-attached antenna 11 is installed in the electromagnetic wave testing device 1. The electromagnetic wave testing device 1 may have a configuration not including the electromagnetic stirrer 13. In this case, an externally-attached electromagnetic stirrer 13 is installed in the electromagnetic wave testing device 1.

The reverberation chamber 10 is, for example, a cavity resonator configured as a metal casing that can house a test object TM. Hereinafter, as an example, a case in which the reverberation chamber 10 is a metal cavity resonator with a parallelepiped shape that can house a test object TM inside as illustrated in FIG. 1 will be described. The shape of the reverberation chamber 10 may be another shape that can house a test object TM instead of a parallelepiped shape. However, in order to easily calculate a resonant frequency of the reverberation chamber 10, it is preferable that the shape of the reverberation chamber 10 be a parallelepiped shape. Hereinafter, for the convenience of description, a lowest-order resonant frequency of the reverberation chamber 10 will be referred to as a first resonant frequency in description. The reverberation chamber 10 may be configured using a cavity resonator configured as a metal casing that can house a test object TM, an antenna 11, and an electromagnetic stirrer 13. In such a case, the electromagnetic wave testing device 1 includes a reverberation chamber 10 and a mounting stand 12.

The antenna 11 emits electromagnetic waves of frequencies lower than the first resonant frequency. The antenna 11 may be any antenna as long as it is an antenna that can be used for a TLS such as a Transverse Electro-Magnetic (TEM) plate antenna, a strip line, a septum, or the like. In other words, the antenna 11 is installed inside the reverberation chamber 10 and enables the electromagnetic wave testing device 1 to function as a TLS. The antenna 11 is connected to an information processing device 2 that is installed outside the reverberation chamber 10 via a communication cable. In other words, the antenna 11 acquires a radio frequency (RF) signal from the information processing device 2 and emits electromagnetic waves corresponding to the acquired RF signal. The electromagnetic wave testing device 1 may be configured to include the information processing device 2.

The mounting stand 12 is a flat plate-shaped stand with a mounting surface made of a conductor on which a test object TM is placed. The entire mounting stand 12 may be made of a conductor, or at least a part thereof other than the mounting surface may be a non-conductor. Hereinafter, as an example, a case in which the entire mounting stand 12 is made of metal, in other words, the entire mounting stand 12 is made of a conductor will be described. The mounting surface may be made of, instead of metal, a conductor other than metal. The mounting surface of the mounting stand 12 is grounded by a member that is omitted in FIG. 1 for simplicity of the drawing. Thus, the electric potential of the mounting surface of the mounting stand 12 is a ground electric potential. For this reason, the mounting stand 12 may be referred to as a ground plane, a reference ground plane, or the like. Hereinafter, as an example, a case in which the mounting surface is a face parallel to a floor face of the reverberation chamber 10 will be described. In addition, hereinafter, as an example, a case in which the floor face of the reverberation chamber 10 is orthogonal to the Z axis will be described. The mounting surface may be a face that is not parallel to the floor face of the reverberation chamber 10. In addition, the floor face of the reverberation chamber 10 may be configured to be oblique to the Z axis. The mounting stand 12 is supported by a support body not illustrated in FIG. 1 such that the height of the mounting stand 12 from the floor face of the reverberation chamber 10 is a height determined in advance. This support body is insulated from the floor face of the reverberation chamber 10. For example, this support body is made of aluminum and is insulated from the floor face of the reverberation chamber 10 using a caster made of resin.

The mounting surface of the mounting stand 12 includes a first side 121 and a second side 122 facing the first side 121. Each of the first side 121 and the second side 122 is also a side that constitutes the external shape of the mounting stand 12. The shape of the mounting stand 12 may be any shape as long as it is a shape having mounting surfaces including a first side 121 and a second side 122. Hereinafter, as an example, a case in which the shape of the mounting stand 12 acquired in a case in which the mounting stand 12 is seen in a direction toward the floor face of the reverberation chamber 10 among directions orthogonal to the mounting surface is a rectangle shape having the first side 121 and the second side 122 as long sides will be described. In other words, in this example, the shape of the mounting stand 12 is a rectangular flat plate shape. In this example, the mounting surface is a top face of the mounting stand 12. Hereinafter, for the convenience of description, a direction toward the floor face of the reverberation chamber 10 among directions orthogonal to the mounting surface will be referred to as a first direction in description. In this example, the first direction coincides with the direction of gravity.

In addition, for example, in case of being in compliance with ISO 11452-2 that is an international standard, the shape of the mounting stand 12 is specified as a rectangular flat plate shape in which the length of a long side is 2000 mm or more, the length of a short side is 1000 mm or more, and a thickness is 0.5 mm or more. In that case, it is also specified that the mounting stand 12 is one of a copper plate, a brass plate, and a galvanized steel plate. However, such specifications are specifications in case of being in compliance with ISO 11452-2. The mounting stand 12 according to this embodiment does not necessarily need to comply with such specifications. The reason for this is that ISO 11452-2 is an international standard for a radiation immunity test using an anechoic chamber but not for a radiation immunity test using the hybrid method. In addition, if an international standard for a radiation immunity test using the hybrid method is established, the mounting stand 12 may be formed in a shape that is in compliance with the established international standard.

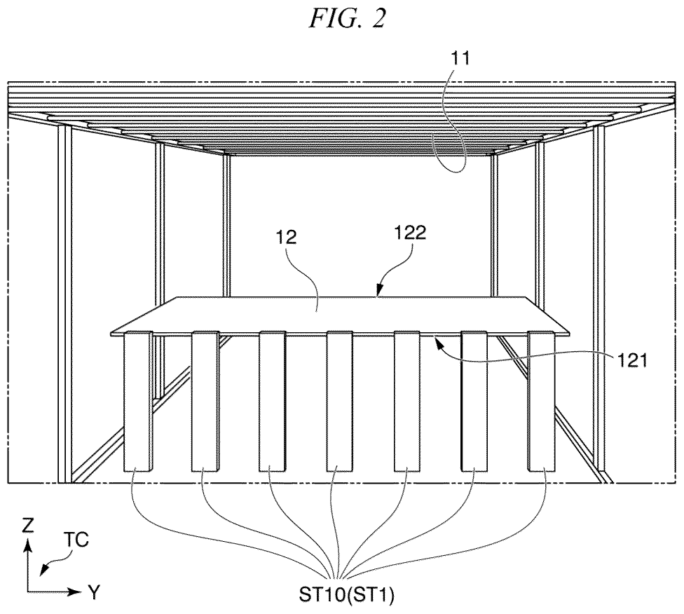

Here, FIG. 2 is an enlarged perspective view of the mounting stand 12 illustrated in FIG. 1. In FIG. 2, in order to prevent complications of the drawing, the support body described above is omitted. As illustrated in FIG. 2, a first grounding part ST1 that electrically connects an object having the ground electric potential and the mounting stand 12 to each other is disposed in the first side 121 of the mounting stand 12. In the example illustrated in FIG. 2, the object having the ground electric potential is a floor face of the reverberation chamber 10. In addition, the object having the ground electric potential may be a side wall face of the reverberation chamber 10 or a ceiling face of the reverberation chamber 10 instead of the floor face of the reverberation chamber 10 and may be an object separated from the reverberation chamber 10 as long as it is an object having the ground electric potential.

In the example illustrated in FIG. 2, the first grounding part ST1 includes seven first grounding members ST10 made of conductors that electrically connect the floor face of the reverberation chamber 10 and the first side 121 to each other. Each of these seven first grounding members ST10 is, for example, a belt-shaped member of which the width of a short side is a first width determined in advance and which connects the floor face and the first side 121 to each other at a shortest distance. In addition, the shapes of at least one of the seven first grounding members ST10 may be other shapes instead of the belt shape. The number of first grounding members ST10 included in the first grounding part ST1 may be one, equal to or greater than two and equal to or smaller than six, or eight or more. For this reason, the first width may be any width as long as it is a width equal to or less than the width of the first side 121 in a direction parallel to the Y axis. In the example illustrated in FIG. 2, two first grounding members ST10 adjacent to each other among these seven first grounding members ST10 are separated from each other in this direction. However, at least one of the two first grounding members ST10 adjacent to each other among these seven first grounding members ST10 may not be separated from each other in that direction.

In case of being in compliance with ISO 11452-2, a distance between the first grounding members ST10 for every two first grounding members ST10 adjacent to each other among the seven first grounding members ST10 described above is specified not to exceed 300 mm. In addition, in that case, a maximum ratio of the height of each of these seven first grounding members ST10 in a direction parallel to the Z axis to the width of each of these seven first grounding members ST10 in the direction parallel to the Y axis is specified to be 7:1. However, similar to the mounting stand 12, each of these seven first grounding members ST10 does not necessarily need to comply with such specifications.

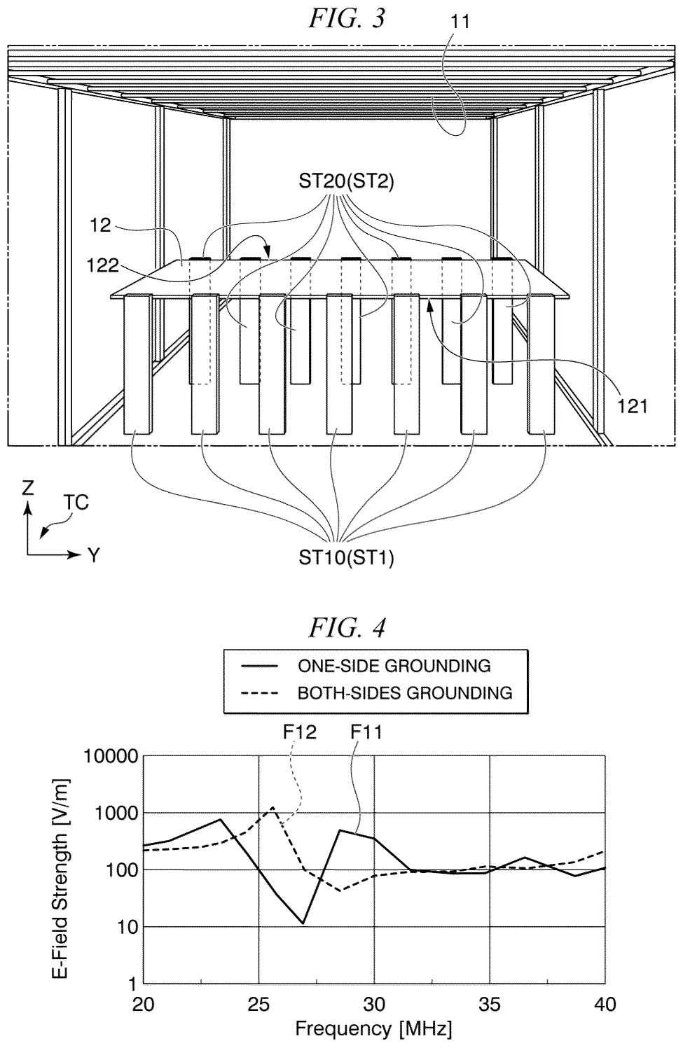

In the example illustrated in FIG. 2, there is no member electrically connecting the object having the ground electric potential and the mounting stand 12 to each other on the second side 122 of the mounting stand 12. However, as illustrated in FIG. 3, the mounting stand 12 may have a configuration in which the first grounding part ST1 is disposed on the first side 121, and the second grounding part ST2 is disposed on the second side 122.

FIG. 3 is an enlarged perspective view of the mounting stand 12 to which the second grounding part ST2 is connected together with the first grounding part ST1. Also in FIG. 3, in order to prevent complications of the drawing, the support body described above is omitted. On the first side 121 of the mounting stand 12 illustrated in FIG. 3, similar to the example illustrated in FIG. 2, a first grounding part ST1 that electrically connects the floor face of the reverberation chamber 10 and the mounting stand 12 to each other is disposed. On the other hand, on the second side 122 of the mounting stand 12 illustrated in FIG. 3, a second grounding part ST2 that electrically connects the floor face of the reverberation chamber 10 and the mounting stand 12 to each other is disposed. Also in the example illustrated in FIG. 3, the floor face of the reverberation chamber 10 is an example of an object having the ground electric potential.

The configuration of the first grounding part ST1 illustrated in FIG. 3 is similar to the configuration of the first grounding part ST1 illustrated in FIG. 2. For this reason, in FIG. 3, description of the first grounding part ST1 will be omitted. On the other hand, the second grounding part ST2 includes seven second grounding members ST20 made of conductors that electrically connect the floor face of the reverberation chamber 10 and the second side 122 to each other. Each of these seven second grounding members ST20 is, for example, a belt-shaped member of which the width of a short side is a second width determined in advance and which connects the floor face and the second side 122 to each other at a shortest distance. In addition, the shapes of at least one of the seven second grounding members ST20 may be other shapes instead of the belt shape. The number of second grounding members ST20 included in the second grounding part ST2 may be one, equal to or greater than two and equal to or smaller than six, or eight or more. For this reason, the second width may be any width as long as it is a width equal to or less than the width of the second side 122 in a direction parallel to the Y axis. In the example illustrated in FIG. 3, two second grounding members ST20 adjacent to each other among these seven second grounding members ST20 are separated from each other in this direction. However, at least one of the two second grounding members ST20 adjacent to each other among these seven second grounding members ST20 may not be separated from each other in that direction.

In case of being in compliance with ISO 11452-2, a distance between the second grounding members ST20 for every two second grounding members ST20 adjacent to each other among the seven second grounding members ST20 described above is also specified not to exceed 300 mm. In addition, in that case, a maximum ratio of the height of each of these seven second grounding members ST20 in a direction parallel to the Z axis to the width of each of these seven second grounding members ST20 in the direction parallel to the Y axis is also specified to be 7:1. However, similar to the mounting stand 12 and the first grounding member ST10, each of these seven second grounding members ST20 does not necessarily need to comply with such specifications.

As described above, the mounting stand 12 is grounded by the first grounding part ST1 or is grounded by both the first and second grounding parts ST1 and ST2. In accordance with this, the electromagnetic wave testing device 1 can suppress the result of the radiation immunity test from changing in accordance with the electric potential of the mounting stand 12.

The electromagnetic stirrer 13 stirs electromagnetic waves inside the reverberation chamber 10. In accordance with this, the reverberation chamber 10 can reduce variations of the electric field strength inside the reverberation chamber 10. The electromagnetic stirrer 13 may have any configuration as long as it is a configuration in which electromagnetic waves inside the reverberation chamber 10 can be stirred. In the example illustrated in FIG. 1, the electromagnetic stirrer 13 includes a shaft body, four stirring blades, which have a flat rectangular shape, disposed on the shaft body to be aligned along the shaft body, and a drive unit that rotates the shaft body. In this case, the electromagnetic stirrer 13 is controlled by the information processing device 2 to stir electromagnetic waves inside the reverberation chamber 10 using the four stirring blades rotating together with the shaft body. Accordingly, the information processing device 2 controls the drive unit and rotates the shaft body. For this reason, the electromagnetic stirrer 13 is connected to the information processing device 2 via a communication cable.

### Uniformity of Electric Field Strength inside Reverberation Chamber in Radiation Immunity Test using Hybrid Method

Hereinafter, the uniformity of electric field strength inside a reverberation chamber in a radiation immunity test using the hybrid method will be described. In a case in which the mounting stand 12 is installed inside the reverberation chamber 10, it is frequently located near the center of the reverberation chamber 10. For this reason, hereinafter, as an example, a case in which the mounting stand 12 is installed near the center of the inside of the reverberation chamber 10 will be described. In addition, the mounting stand 12 may be installed at a position different from a position near the center of the inside of the reverberation chamber 10.

Here, in the transmission line system method, the adjustment of electric field strength of the inside of the reverberation chamber 10 in a case in which a radiation immunity test is conducted is performed in a state in which only the antenna 11 and electromagnetic stirrer 13 are installed inside the reverberation chamber 10. In other words, this adjustment is performed in a state in which the mounting stand 12 is not installed inside the reverberation chamber 10. More specifically, the adjustment is performed such that an average value of the electric field strength at a plurality of measurement positions determined in advance inside the reverberation chamber 10 in which the mounting stand 12 is not installed is electric field strength determined in advance as electric field strength applied to a test object TM in a radiation immunity test. Then, the mounting stand 12 is installed inside the reverberation chamber 10 after this adjustment is performed, and the radiation immunity test is conducted on a test object TM placed on the mounting stand 12. Hereinafter, for the convenience of description, electric field strength determined in advance as an electric field strength applied to a test object TM in a radiation immunity test will be referred to as test electric field strength in description. In addition, hereinafter, for the convenience of description, this average value after the adjustment will be referred to as post-adjustment electric field strength in description.

FIG. 4 is a diagram illustrating a frequency spectrum of electric field strength detected by an electric field sensor installed near the center of a mounting surface. FIG. 4 illustrates a frequency spectrum within the range of 20 MHz to 40 MHz. A horizontal axis of a graph illustrated in FIG. 4 represents the frequency. The vertical axis of this graph represents the electric field strength. A curve F11 plotted in this graph illustrates an example of a frequency spectrum of electric field strength detected by this electric field sensor in a case in which the floor face of the reverberation chamber 10 and the mounting stand 12 are connected using the first grounding part ST1, and the floor face of the reverberation chamber 10 and the mounting stand 12 are not connected using the second grounding part ST2. In the example illustrated in FIG. 4, the curve F11 is indicated by label “one-side grounding”. A curve F12 plotted in this graph illustrates an example of a frequency spectrum of electric field strength detected by this electric field sensor in a case in which the floor face of the reverberation chamber 10 and the mounting stand 12 are connected using both the first grounding part ST1 and the second grounding part ST2. In the example illustrated in FIG. 4, the curve F12 is indicated by label “both-sides grounding”.

In the example illustrated in FIG. 4, the dimensions of the reverberation chamber 10 are 10.08 m×6.36 m×4.00 m, the first resonant frequency is 80 MHz, the TLS configured using the antenna 11 with the length of a metal wire being 3 m is disposed at a height of 1.9 m, the length of the long side of the mounting stand 12 is 3 m, the length of the short side of the mounting stand 12 is 1.5 m, the height of the mounting stand 12 from the floor face of the reverberation chamber 10 is 0.9 m, and the rotation steps of the electromagnetic stirrer 13 are 6 steps. In this example, power supplied to the antenna 11 is the same power as power that is supplied to the antenna 11 in a case in which adjustment is performed such that the post-adjustment electric field strength becomes 100 V/m. In the example, a distance between the first grounding members ST10 that are adjacent to each other in a case in which the first grounding part ST1 is connected to the mounting stand 12, and the second grounding part ST2 is not connected to the mounting stand 12 is 300 mm. In addition, in this example, in a case in which both the first grounding part ST1 and the second grounding part ST2 are connected to the mounting stand 12, each of the distance between the first grounding members ST10 that are adjacent to each other and the distance between the second grounding members ST20 that are adjacent to each other is 300 mm. In this example, in a case in which the first grounding part ST1 is connected to the mounting stand 12, and the second grounding part ST2 is not connected to the mounting stand 12, the width of the first grounding member ST10 in a direction parallel to the Y axis is 150 mm. In addition, in this example, in a case in which both the first grounding part ST1 and the second grounding part ST2 are connected to the mounting stand 12, each of the width of the first grounding member ST10 in this direction and the width of the second grounding member ST20 in this direction is 150 mm. Each of the curves F11 and F12 illustrated in FIG. 3 is a result of extracting the frequency spectrum of the electric field strength in the range of 20 MHz to 40 MHz from the frequency spectrum of the electric field strength in the range of 10 kHz to 250 MHz.

When the curves F11 and F12 are compared with each other, it can be understood that, in a case in which the first grounding part ST1 is connected to the mounting stand 12, and the second grounding part ST2 is not connected to the mounting stand 12, the electric field strength near the frequency of 27.5 MHz is greatly reduced near the center of the mounting surface. In other words, when the curves F11 and F12 are compared with each other, it can be understood that, in a case in which both the first grounding part ST1 and the second grounding part ST2 are connected to the mounting stand 12, the reduction of the electric field strength near the center of the mounting surface is suppressed. Hereinafter, for the convenience of description, a case in which the first grounding part ST1 is connected to the mounting stand 12, and the second grounding part ST2 is not connected to the mounting stand 12 will be referred to as one-side grounding in description. In addition, hereinafter, for the convenience of description, a case in which both the first grounding part ST1 and the second grounding part ST2 are connected to the mounting stand 12 will be referred to as both-sides grounding in description.

Naturally, the reduction of the electric field strength at around 27.5 MHz, as indicated by the curve F11, can be compensated for by amplifying the power supplied to the antenna 11. For this reason, even in a case in which the second grounding part ST2 is not included, the electromagnetic wave testing device 1 can sufficiently conduct a radiation immunity test using the hybrid method. However, the electric field strength at 27.5 MHz in the curve F12 is about 9 times the electric field strength at 27.5 MHz in the curve F11. In order to compensate for nine times the electric field strength, the power supplied to the antenna 11 needs to be increased by 81 times. The cost of introduction of power amplifiers to make such compensation is very high. From such situations, it can be understood that the electromagnetic wave testing device 1 preferably includes the second grounding part ST2.

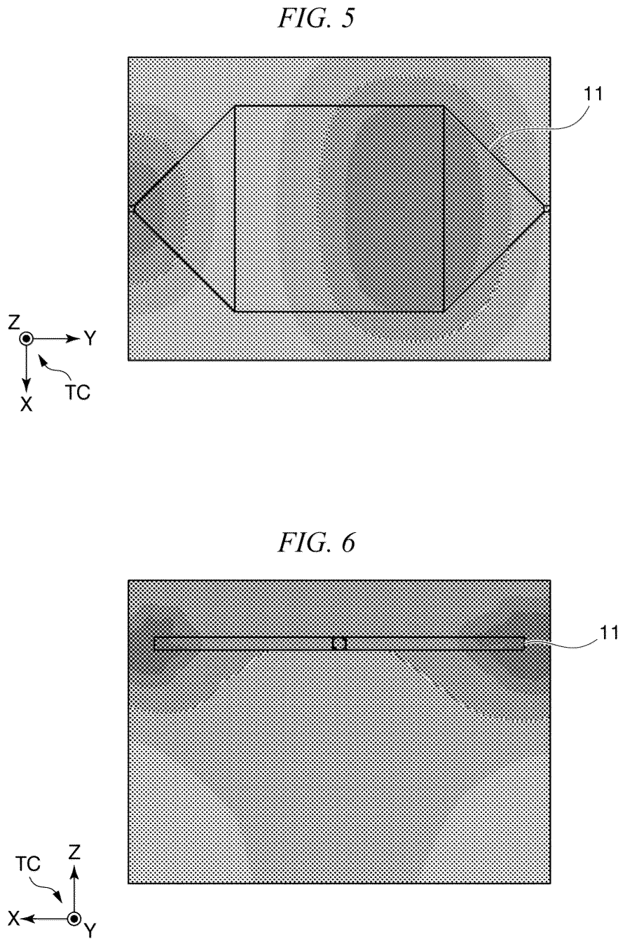

Here, FIG. 5 is a diagram illustrating an example of a result of analysis of a distribution of electric field strength of 27.5 MHz inside a reverberation chamber 10 using a finite element method in a case in which the reverberation chamber 10, in which a mounting stand 12 is not installed, is seen in a negative direction of a Z axis. FIG. 6 is a diagram illustrating an example of a result of analysis of a distribution of electric field strength of 27.5 MHz inside a reverberation chamber 10 using a finite element method in a case in which the reverberation chamber 10, in which the mounting stand 12 is not installed, is seen in a negative direction of a Y axis. In FIGS. 5 and 6, the strength/weakness of the electric field strength is indicated by the shading of hatching. More specifically, in FIGS. 5 and 6, the electric field strength of a lightly hatched area is weaker than the electric field strength of a darkly hatched area. As illustrated in FIGS. 5 and 6, inside the reverberation chamber 10 in which the mounting stand 12 is not installed, the variation of the electric field strength is small.

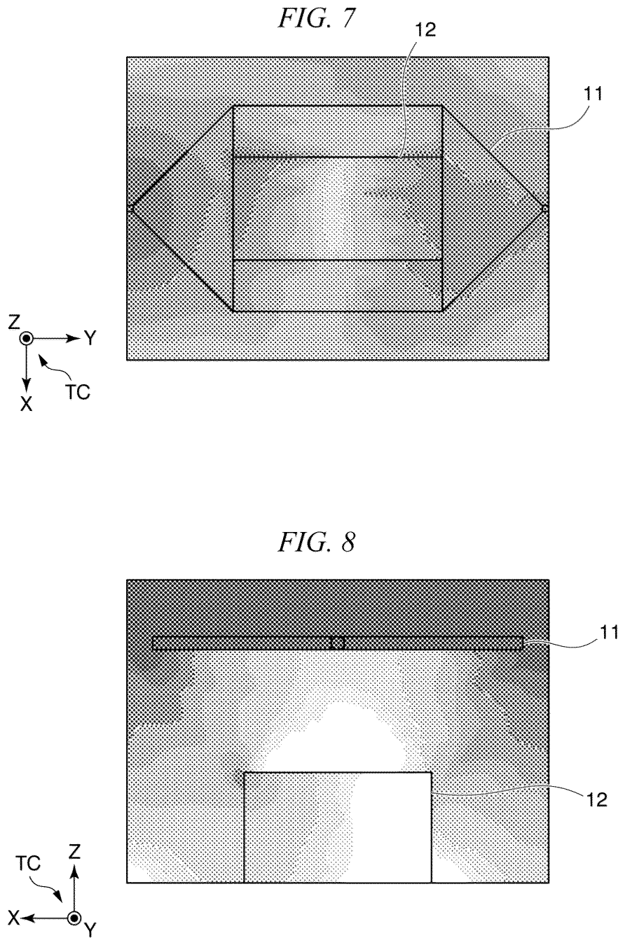

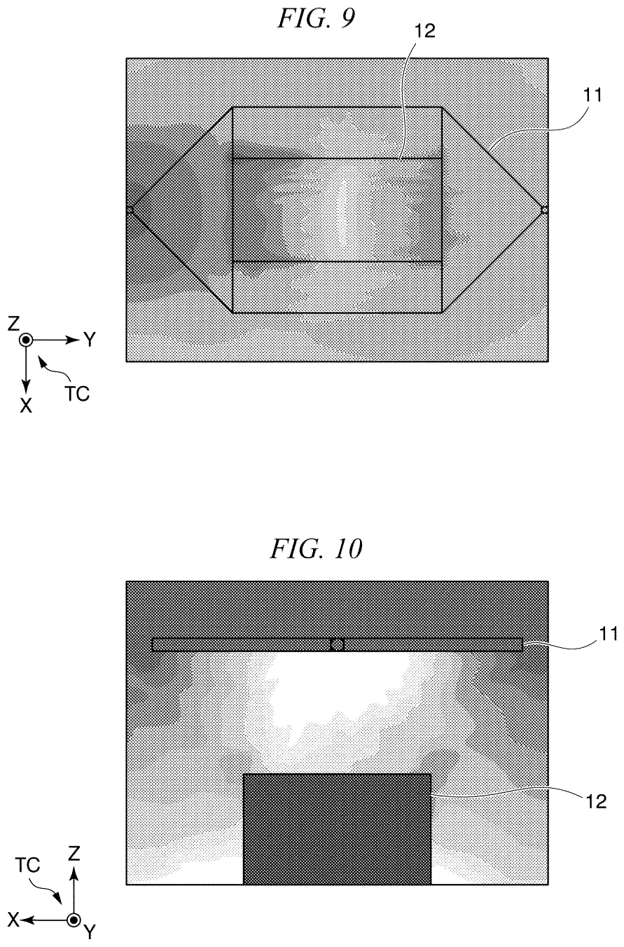

FIG. 7 is a diagram illustrating an example of a result of analysis of a distribution of electric field strength of 27.5 MHz inside a reverberation chamber 10 using a finite element method in a case in which the reverberation chamber 10, in which the one-side grounded mounting stand 12 as illustrated in FIG. 2 is installed, is seen in a negative direction of a Z axis. FIG. 8 is a diagram illustrating an example of a result of analysis of a distribution of electric field strength of 27.5 MHz inside a reverberation chamber 10 using a finite element method in a case in which the reverberation chamber 10, in which the one-side grounded mounting stand 12 is installed as illustrated in FIG. 2, is seen in a negative direction of the Y axis. In FIG. 8, in order to prevent complications of the drawing, the mounting stand 12 and the support body are drawn as one object having a rectangular shape. Also in FIGS. 7 and 8, the strength/weakness of the electric field strength is indicated by the shading of hatching. More specifically, in FIGS. 7 and 8, the electric field strength of a lightly hatched area is weaker than the electric field strength of a darkly hatched area. As illustrated in FIGS. 7 and 8, inside the reverberation chamber 10 in which the one-side grounded mounting stand 12 is installed, the variation of the electric field strength is larger than that in a case in which the mounting stand 12 is not installed inside the reverberation chamber 10. More specifically, inside the reverberation chamber 10 in which a one-side grounded mounting stand 12 is installed, the electric field strength near the center of the mounting surface is extremely lower than the electric field strength of the other areas. However, as illustrated in FIGS. 9 and 10, inside the reverberation chamber 10 in which a both-sides grounded mounting stand 12 is installed, a degree of reduction of the electric field strength near the center of the mounting surface is mitigated compared to that inside of a reverberation chamber 10 in which a one-side grounded mounting stand 12 is installed.

FIG. 9 is a diagram illustrating an example of a result of analysis of a distribution of electric field strength of 27.5 MHz inside a reverberation chamber 10 using a finite element method in a case in which the reverberation chamber 10, in which a both-sides grounded mounting stand 12 is installed as illustrated in FIG. 3, is seen in a negative direction of the Z axis. FIG. 10 is a diagram illustrating an example of a result of analysis of a distribution of electric field strength of 27.5 MHz inside a reverberation chamber 10 using a finite element method in a case in which the reverberation chamber 10, in which the both-sides grounded mounting stand 12 is installed as illustrated in FIG. 3, is seen in a negative direction of the Y axis. In FIG. 10, in order to prevent complications of the drawing, the mounting stand 12 and the support body are drawn as one object having a rectangular shape. Also in FIGS. 9 and 10, the strength/weakness of the electric field strength is indicated by the shading of hatching. More specifically, in FIGS. 9 and 10, the electric field strength of a lightly hatched area is weaker than the electric field strength of a darkly hatched area. As illustrated in FIGS. 9 and 10, inside the reverberation chamber 10 in which the both-sides grounded mounting stand 12 is installed, a degree of reduction of the electric field strength near the center of the mounting surface is mitigated compared to that inside the reverberation chamber 10 in which the one-side grounded mounting stand 12 is installed. This is a result that is not contradictory to the graph illustrated in FIG. 3. In other words, in a radiation immunity test using the hybrid method, by including the both-sides grounded mounting stand 12, the electromagnetic wave testing device 1 can reduce the variation of the electric field strength on the mounting stand 12. In other words, by grounding the mounting stand 12 inside the reverberation chamber 10 using both-sides grounding, the electromagnetic wave testing device 1 can improve the uniformity of the electric field strength on the mounting stand 12. The leads to prevention of the result of this radiation immunity test from being underestimated, which is useful.

### Mode of Connection of First Grounding Part and Second Grounding Part to Mounting Stand

In the analysis illustrated in FIGS. 9 and 10, both the width of the first grounding member ST10 in a direction parallel to the Y axis and the width of the second grounding member ST20 in this direction are set to 150 mm. In this analysis, the length of the long sides of the mounting stand 12, that is, the length of the first side 121 and the second side 122 are set to 3 meters. In this analysis, each of the distance between the first grounding members ST10 that are adjacent to each other and the distance between the second grounding members ST20 that are adjacent to each other is set to 300 mm. In other words, in this analysis, the mounting stand 12 is grounded through both-sides grounding, the first grounding members ST10 are separated from each other, and the second grounding members ST20 are also separated from each other. However, modes of connection of the first grounding member ST10 and the second grounding member ST20 to the mounting stand 12 are not limited to these. Thus, here, a specific example of the mode of connection of each of the first grounding member ST10 and the second grounding member ST20 to the mounting stand 12 described in this embodiment will be described. Hereinafter, for the convenience of description, a specific example of the mode of connection of each of the first grounding member and the second grounding member to the mounting stand 12 described in this embodiment will be referred to as each of first to ninth connection modes in description.

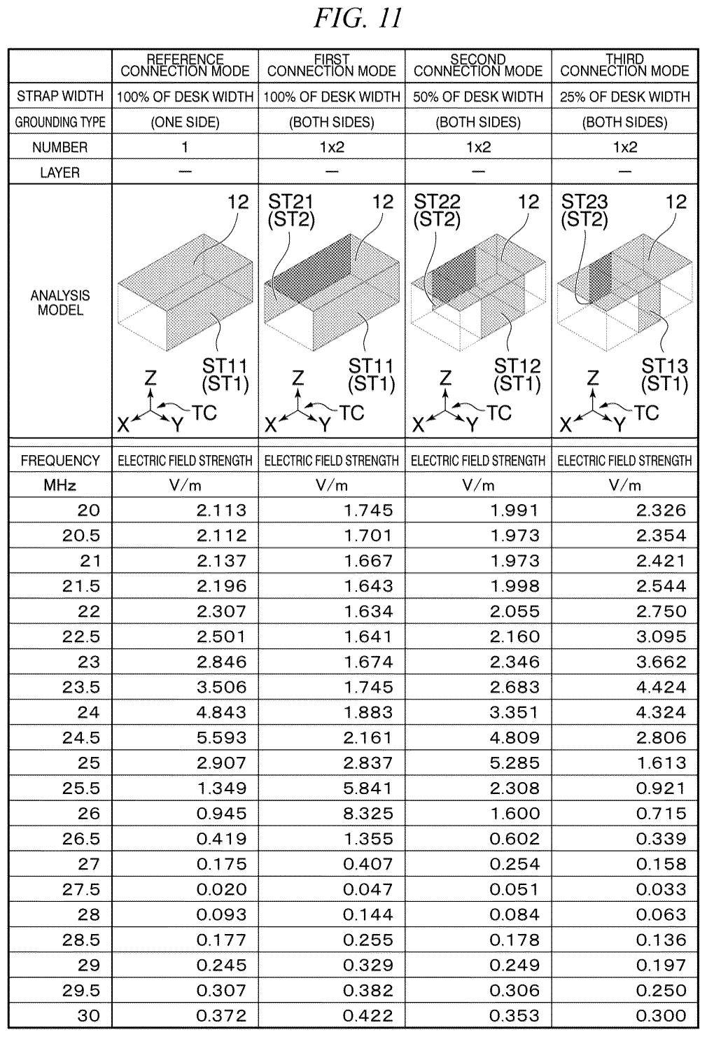

The first connection mode is a mode in which the first grounding member ST10 of which the width in the direction parallel to the Y-axis is the same as the length of the first side 121 is just one, connected to the first side 121, and the second grounding member ST20 of which the width in that direction is the same as the length of the second side 122 is just one, connected to the second side 122. Hereinafter, for the convenience of description, the first grounding member ST10 in the first connection mode will be referred to as a first grounding member ST11, and the second grounding member ST20 in the first connection mode will be referred to as a second grounding member ST21. In the first connection mode, the first grounding member ST11 is connected from the first side 121 to the floor face of the reverberation chamber 10 at the shortest distance. In addition, in the first connection mode, the second grounding member ST21 is connected from the second side 122 to this floor face at the shortest distance. In the first connection mode, a virtual first surface is entirely filled by the first grounding member ST11. This virtual first surface is a rectangular surface having two sides. One of these two sides is the area on the floor surface in which the first side 121 is projected onto the floor surface in the first direction. The other of these two sides is the first side 121. In addition, in the first connection mode, a virtual second surface is entirely filled by the second grounding member ST21. This virtual second surface is a rectangular surface having two sides. One of these two sides is the area on the floor surface in which the second side 122 is projected onto the floor surface in the second direction. The other of these two sides is the second side 122. In other words, in the first connection mode, in a case in which the mounting stand 12 is seen in a second direction from the first side 121 toward the second side 122 among directions that are orthogonal to the first face, the first grounding member ST11 completely covers the first face except for error due to distortion, deformation, or the like of the first grounding member ST11. In addition, in the first connection mode, in a case in which the mounting stand 12 is seen in a third direction from the second side 122 toward the first side 121 among directions that are orthogonal to the second face, the second grounding member ST21 completely covers the second face except for error due to distortion, deformation, or the like of the second grounding member ST21. The first connection mode is illustrated as a diagram illustrating an analysis model of the first connection mode in FIG. 11 to be described below. The analysis model of the first connection mode is an analysis model used for analyzing the electric field strength near the center of the mounting surface in a case in which each of the first grounding part ST1 and the second grounding part ST2 is connected to the mounting stand 12 in the first connection mode.

The second connection mode is a mode in which a first grounding member ST10 of which a width in a direction parallel to the Y axis is a width of 50% of the length of a first side 121 is just one, connected to the first side 121, and a second grounding member ST20 of which a width in this direction is a width of 50% of the length of a second side 122 is just one, connected to the second side 122. Hereinafter, for the convenience of description, the first grounding member ST10 in the second connection mode will be referred to as a first grounding member ST12, and the second grounding member ST20 in the second connection mode will be referred to as a second grounding member ST22 in description. In the second connection mode, the first grounding member ST12 is connected from the first side 121 to the floor face of the reverberation chamber 10 at the shortest distance. In addition, in the second connection mode, the second grounding member ST22 is connected from the second side 122 to this floor face at the shortest distance. In the second connection mode, the first grounding member ST12 is connected to the first side 121 such that a midpoint of the first side 121 and a midpoint of a first end part connected to the first side 121 among end parts of the first grounding member ST12 in this direction coincide with each other. In addition, in the second connection mode, the second grounding member ST22 is connected to the second side 122 such that a midpoint of the second side 122 and a midpoint of a second end part connected to the second side 122 among end parts of the second grounding member ST22 in this direction coincide with each other. In the second connection mode, 50% of the first face is covered with the first grounding member ST12. In addition, in the second connection mode, 50% of the second face is covered with the second grounding member ST22. In other words, in the second connection mode, in a case in which the mounting stand 12 is seen in the second direction, the first grounding member ST12 covers 50% of the first face except for error due to distortion, deformation, or the like of the first grounding member ST12. In addition, in the second connection mode, in a case in which the mounting stand 12 is seen in the third direction, the second grounding member ST22 covers 50% of the second face except for error due to distortion, deformation, or the like of the second grounding member ST22. The second connection mode is illustrated as a diagram illustrating an analysis model of the second connection mode in FIG. 11 to be described below. The analysis model of the second connection mode is an analysis model used for analyzing the electric field strength near the center of the mounting surface in a case in which each of the first grounding part ST1 and the second grounding part ST2 is connected to the mounting stand 12 in the second connection mode.

The third connection mode is a mode in which a first grounding member ST10 of which a width in a direction parallel to the Y axis is a width of 25% of the length of a first side 121 is just one, connected to the first side 121, and a second grounding member ST20 of which a width in this direction is a width of 25% of the length of a second side 122 is just one, connected to the second side 122. Hereinafter, for the convenience of description, the first grounding member ST10 in the third connection mode will be referred to as a first grounding member ST13, and the second grounding member ST20 in the third connection mode will be referred to as a second grounding member ST23 in description. In the third connection mode, the first grounding member ST13 is connected from the first side 121 to the floor face of the reverberation chamber 10 at the shortest distance. In addition, in the third connection mode, the second grounding member ST23 is connected from the second side 122 to this floor face at the shortest distance. In the third connection mode, the first grounding member ST13 is connected to the first side 121 such that a midpoint of the first side 121 and a midpoint of the first end part in this direction coincide with each other. In addition, in the third connection mode, the second grounding member ST23 is connected to the second side 122 such that a midpoint of the second side 122 and a midpoint of the second end part in this direction coincide with each other. In the third connection mode, 25% of the first face is covered with the first grounding member ST13. In addition, in the third connection mode, 25% of the second face is covered with the second grounding member ST23. In other words, in the third connection mode, in a case in which the mounting stand 12 is seen in the second direction, the first grounding member ST13 covers 25% of the first face except for error due to distortion, deformation, or the like of the first grounding member ST13. In addition, in the third connection mode, in a case in which the mounting stand 12 is seen in the third direction, the second grounding member ST23 covers 25% of the second face except for error due to distortion, deformation, or the like of the second grounding member ST23. The third connection mode is illustrated as a diagram illustrating an analysis model of the third connection mode in FIG. 11 to be described below. The analysis model of the third connection mode is an analysis model used for analyzing the electric field strength near the center of the mounting surface in a case in which each of the first grounding part ST1 and the second grounding part ST2 is connected to the mounting stand 12 in the third connection mode.

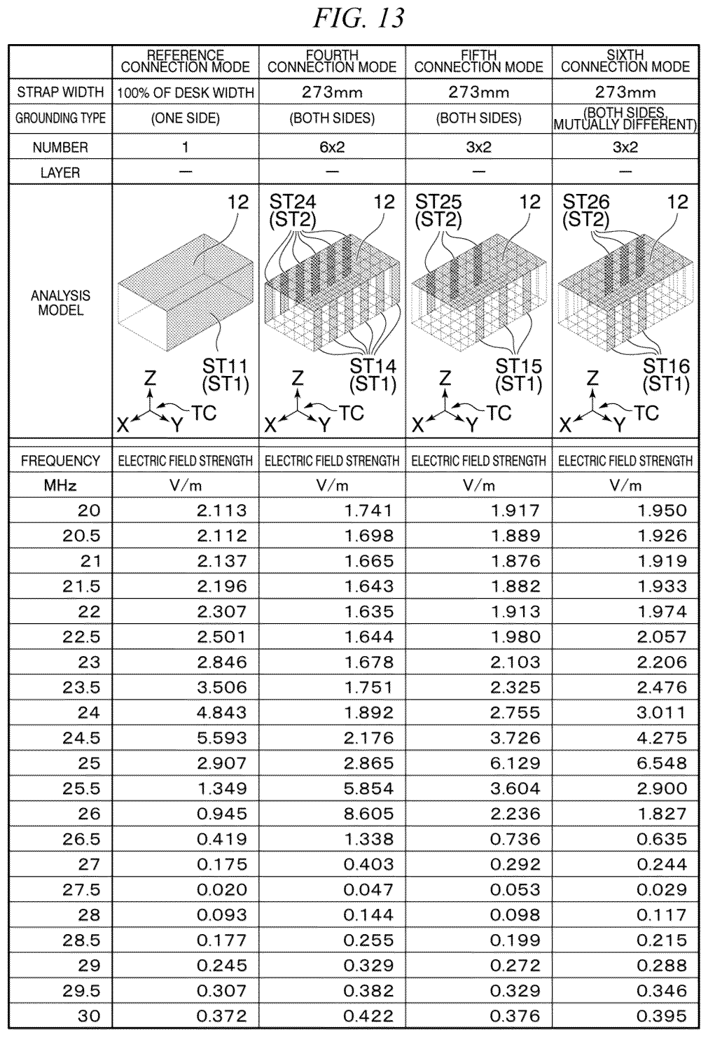

The fourth connection mode is a mode in which the six first grounding members ST10 of which a width in a direction parallel to the Y axis is 273 mm is connected to the first side 121, and the six second grounding members ST20 of which a width in this direction is 273 mm is connected to the second side 122. Hereinafter, for the convenience of description, the first grounding member ST10 in the fourth connection mode will be referred to as a first grounding member ST14, and the second grounding member ST20 in the fourth connection mode will be referred to as a second grounding member ST24 in description. In the fourth connection mode, each of the six first grounding members ST14 is connected from the first side 121 to the floor face of the reverberation chamber 10 at the shortest distance. In addition, in the fourth connection mode, each of the six second grounding members ST24 is connected from the second side 122 to this floor face at the shortest distance. In the fourth connection mode, the first grounding members ST14, which are adjacent to each other, among the six first grounding members ST14 are separated from each other by 273 mm in this direction. In addition, in the fourth connection mode, the second grounding members ST24, which are adjacent to each other, among the six second grounding members ST24 are separated from each other by 273 mm in this direction. In the fourth connection mode, an end part of the first grounding member ST14 of the most positive-direction side of the X axis on the most positive-direction side among the six first grounding members ST14 is connected to an end part of the first side 121 on this positive-direction side. In addition, in the fourth connection mode, an end part of the second grounding member ST24 of the most positive-direction side of the X axis on the most positive-direction side among the six second grounding members ST24 is connected to an end part of the second side 122 on this positive-direction side. The fourth connection mode is illustrated as a diagram illustrating an analysis model of the fourth connection mode in FIG. 13 to be described below. The analysis model of the fourth connection mode is an analysis model used for analyzing the electric field strength near the center of the mounting surface in a case in which each of the first grounding part ST1 and the second grounding part ST2 is connected to the mounting stand 12 in the fourth connection mode.

The fifth connection mode is a mode in which the three first grounding members ST10 of which a width in a direction parallel to the Y axis is 273 mm is connected to the first side 121, and the three second grounding members ST20 of which a width in this direction is 273 mm is connected to the second side 122. Hereinafter, for the convenience of description, the first grounding member ST10 in the fifth connection mode will be referred to as a first grounding member ST15, and the second grounding member ST20 in the fifth connection mode will be referred to as a second grounding member ST25 in description. In the fifth connection mode, each of the three first grounding members ST15 is connected from the first side 121 to the floor face of the reverberation chamber 10 at the shortest distance. In addition, in the fifth connection mode, each of the three second grounding members ST25 is connected from the second side 122 to this floor face at the shortest distance. In the fifth connection mode, the first grounding members ST15, which are adjacent to each other, among the three first grounding members ST15 are separated from each other by 546 mm in this direction. In addition, in the fifth connection mode, the second grounding members ST25, which are adjacent to each other, among the three second grounding members ST25 are separated from each other by 546 mm in this direction. In the fifth connection mode, an end part of the first grounding member ST15 of the most positive-direction side of the X axis on the most positive-direction side among the three first grounding members ST15 is separated from an end part of the first side 121 on this positive-direction side by 546 mm in this direction. In addition, in the fifth connection mode, an end part of the second grounding member ST25 of the most positive-direction side of the X axis on the most positive-direction side among the three second grounding members ST25 is separated from an end part of the second side 122 on this positive-direction side by 546 mm in this direction. The fifth connection mode is illustrated as a diagram illustrating an analysis model of the fifth connection mode in FIG. 13 to be described below. The analysis model of the fifth connection mode is an analysis model used for analyzing the electric field strength near the center of the mounting surface in a case in which each of the first grounding part ST1 and the second grounding part ST2 is connected to the mounting stand 12 in the fifth connection mode.

The sixth connection mode is a mode in which the three first grounding members ST10 of which a width in a direction parallel to the Y axis is 273 mm is connected to the first side 121, and the three second grounding members ST20 of which a width in this direction is 273 mm is connected to the second side 122. Hereinafter, for the convenience of description, the first grounding member ST10 in the sixth connection mode will be referred to as a first grounding member ST16, and the second grounding member ST20 in the sixth connection mode will be referred to as a second grounding member ST26 in description. In the sixth connection mode, each of the three first grounding members ST16 is connected from the first side 121 to the floor face of the reverberation chamber 10 at the shortest distance. In addition, in the sixth connection mode, each of the three second grounding members ST26 is connected from the second side 122 to this floor face at the shortest distance. In the sixth connection mode, the first grounding members ST16, which are adjacent to each other, among the three first grounding members ST16 are separated from each other by 273 mm in this direction. In addition, in the sixth connection mode, the second grounding members ST26, which are adjacent to each other, among the three second grounding members ST26 are separated from each other by 273 mm in this direction. In the sixth connection mode, an end part of the first grounding member ST16 of the most positive-direction side of the X axis on the most positive-direction side among the three first grounding members ST16 is connected to an end part of the first side 121 on this positive-direction side. In addition, in the sixth connection mode, an end part of the second grounding member ST26 of the most positive-direction side of the X axis on the most positive-direction side among the three second grounding members ST26 is connected to an end part of the second side 122 on this positive-direction side. The sixth connection mode is illustrated as a diagram illustrating an analysis model of the sixth connection mode in FIG. 13 to be described below. The analysis model of the sixth connection mode is an analysis model used for analyzing the electric field strength near the center of the mounting surface in a case in which each of the first grounding part ST1 and the second grounding part ST2 is connected to the mounting stand 12 in the sixth connection mode.

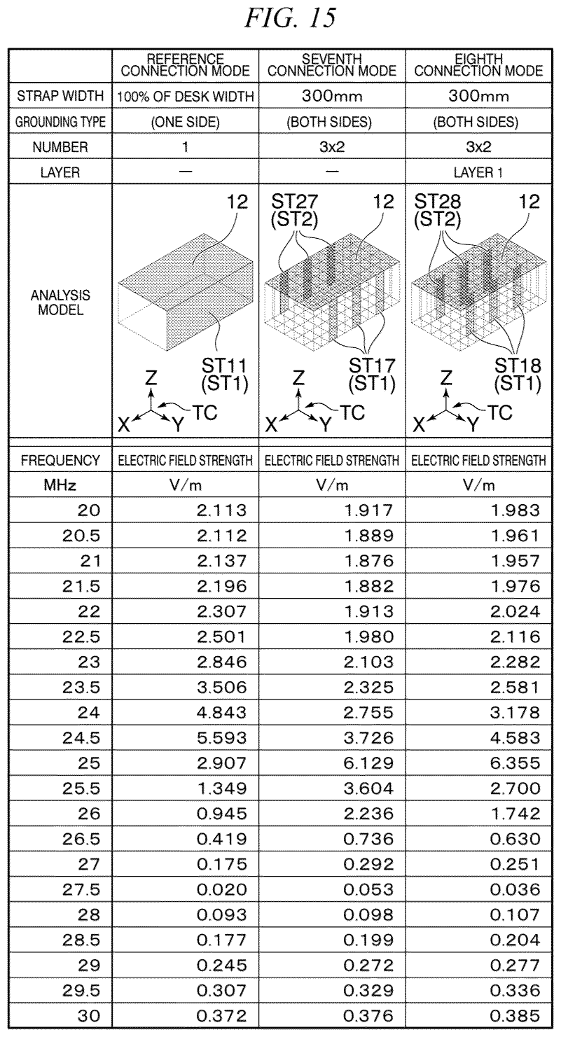

The seventh connection mode is a mode in which the three first grounding members ST10 of which a width in a direction parallel to the Y axis is 300 mm is connected to the first side 121, and the three second grounding members ST20 of which a width in this direction is 300 mm is connected to the second side 122. Hereinafter, for the convenience of description, the first grounding member ST10 in the seventh connection mode will be referred to as a first grounding member ST17, and the second grounding member ST20 in the seventh connection mode will be referred to as a second grounding member ST27 in description. In the seventh connection mode, each of the three first grounding members ST17 is connected from the first side 121 to the floor face of the reverberation chamber 10 at the shortest distance. In addition, in the seventh connection mode, each of the three second grounding members ST27 is connected from the second side 122 to this floor face at the shortest distance. In the seventh connection mode, the first grounding members ST17, which are adjacent to each other, among the three first grounding members ST17 are separated from each other by 600 mm in this direction. In addition, in the seventh connection mode, the second grounding members ST27, which are adjacent to each other, among the three second grounding members ST27 are separated from each other by 600 mm in this direction. In the seventh connection mode, an end part of the first grounding member ST17 of the most positive-direction side of the X axis on the most positive-direction side among the three first grounding members ST17 is separated from an end part of the first side 121 on this positive-direction side by 600 mm in this direction. In addition, in the seventh connection mode, an end part of the second grounding member ST27 of the most positive-direction side of the X axis on the most positive-direction side among the three second grounding members ST27 is separated from an end part of the second side 122 on this positive-direction side by 600 mm in this direction. The seventh connection mode is illustrated as a diagram illustrating an analysis model of the seventh connection mode in FIG. 15 to be described below. The analysis model of the seventh connection mode is an analysis model used for analyzing the electric field strength near the center of the mounting surface in a case in which each of the first grounding part ST1 and the second grounding part ST2 is connected to the mounting stand 12 in the seventh connection mode.

The eighth connection mode is a mode in which the three first grounding members ST10 of which a width in a direction parallel to the Y axis is 300 mm is connected to the first side 121, and the three second grounding members ST20 of which a width in this direction is 300 mm is connected to the second side 122. Hereinafter, for the convenience of description, the first grounding member ST10 in the eighth connection mode will be referred to as a first grounding member ST18, and the second grounding member ST20 in the eighth connection mode will be referred to as a second grounding member ST28 in description. In the eighth connection mode, each of the three first grounding members ST18 is connected from the first side 121 to the floor face of the reverberation chamber 10 at the shortest distance. In addition, in the eighth connection mode, each of the three second grounding members ST28 is connected from the second side 122 to this floor face at the shortest distance. In the eighth connection mode, the first grounding members ST18, which are adjacent to each other, among the three first grounding members ST18 are separated from each other by 600 mm in this direction. In addition, in the eighth connection mode, the second grounding members ST28, which are adjacent to each other, among the three second grounding members ST28 are separated from each other by 600 mm in this direction. In the eighth connection mode, each of the three first grounding members ST18 is separated from the first side 121 by 300 mm in a second direction. In addition, in the eighth connection mode, each of the three second grounding members ST28 is separated from the second side 122 by 300 mm in a third direction. In the eighth connection mode, an end part of the first grounding member ST18 of the most positive-direction side of the X axis on the most positive-direction side among the three first grounding members ST18 is separated from an end part of the positive-direction side among end parts of the mounting stand 12 by 600 mm in the negative direction of the X axis. In addition, in the eighth connection mode, an end part of the second grounding member ST28 of the most positive-direction side of the X axis on the most positive-direction side among the three second grounding members ST28 is separated from an end part of the positive-direction side among end parts of the mounting stand 12 by 600 mm in the negative direction of the X axis. The eighth connection mode is illustrated as a diagram illustrating an analysis model of the eighth connection mode in FIG. 15 to be described below. The analysis model of the eighth connection mode is an analysis model used for analyzing the electric field strength near the center of the mounting surface in a case in which each of the first grounding part ST1 and the second grounding part ST2 is connected to the mounting stand 12 in the eighth connection mode.

### Analysis Result of Electric Field Strength inside Reverberation Chamber in each Connection Mode

Hereinafter, analysis results of the first electric field strength to the eighth electric field strength described above will be described. In this embodiment, n-th electric field strength is an electric field strength inside the reverberation chamber 10 in an n-th connection mode. Here, n is any one integer among 1 to 9. In this embodiment, the electric field strength inside the reverberation chamber 10 in the n-th connection mode is electric field strength near the center of the mounting surface in a case in which each of the first grounding part ST1 and the second grounding part ST2 is connected to the mounting stand 12 in the n-th connection mode. In this embodiment, an analysis result of the n-th electric field strength is a frequency spectrum of the n-th electric field strength acquired as a result of analysis using a finite element method using the analysis model of the n-th connection mode.

FIG. 11 is a diagram illustrating an example of a table comparing an analysis result of reference electric field strength with an analysis result of each of first electric field strength to third electric field strength. Here, the reference electric field strength is electric field strength inside the reverberation chamber 10 in a reference connection mode. The reference connection mode is a connection mode in which, as in the first connection mode, the first grounding member ST11 is connected to the first side 121 of the mounting stand 12, and, different form the first connection mode, the second grounding member ST21 is not connected to the second side 122 of the mounting stand 12. In other words, in the reference connection mode, the electromagnetic wave testing device 1 does not include the second grounding part ST2. In this embodiment, the electric field strength inside the reverberation chamber 10 in the reference connection mode is electric field strength near the center of the mounting surface in a case in which the first grounding part ST1 is connected to the mounting stand 12 in the reference connection mode. In addition, in this embodiment, an analysis result of the reference electric field strength is a frequency spectrum of the reference electric field strength acquired as a result of analysis using a finite element method using the analysis model of the reference connection mode illustrated in FIG. 11.

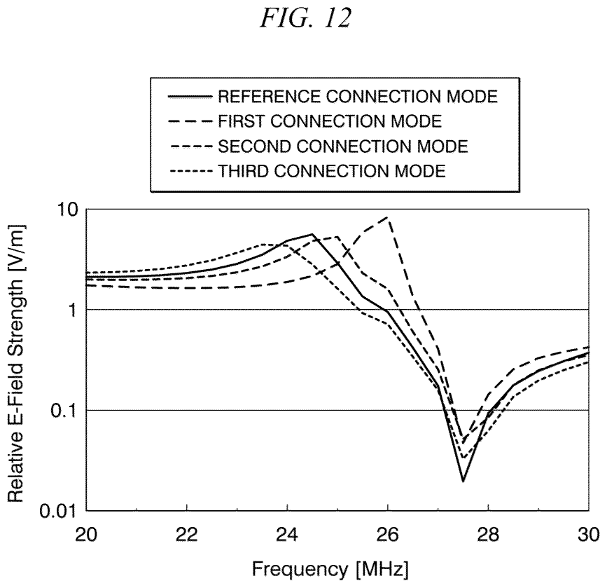

FIG. 11 illustrates a table illustrating an example of an analysis result of each of the reference electric field strength, the first electric field strength, the second electric field strength, and the third electric field strength. The frequency band of the frequency spectrum illustrated in FIG. 11 is 20 MHz to 30 MHz, and an interval between frequencies is 0.5 MHz. FIG. 12 is a diagram illustrating an example of graphs in which the frequency spectra illustrated in FIG. 11 are plotted.

As illustrated in FIG. 12, all the first electric field strength to the third electric field strength decrease at around 27.5 MHz. However, all the first electric field strength to the third electric field strength are stronger than the reference electric field strength at around 27.5 MHz. In other words, this represents that each of the first connection mode to the third connection mode can suppress a decrease in the electric field strength near the center of the mounting surface of the mounting stand 12 compared to the reference connection mode. The first electric field strength at around 27.5 MHz is approximately the same strength as the second electric field strength at around 27.5 MHz. In addition, the first electric field strength and the second electric field strength at around 27.5 MHz are stronger than the third electric field strength at around 27.5 MHz. A ratio of the first face covered with the first grounding part ST1 in a case in which the mounting stand 12 is grounded using the first connection mode is higher than a ratio of the first face covered with the first grounding part ST1 in a case in which the mounting stand 12 is grounded using the second connection mode. This similarly applies also to a ratio of the second face covered with the second grounding part ST2. A ratio of the first face covered with the first grounding part ST1 in a case in which the mounting stand 12 is grounded using the second connection mode is higher than a ratio of the first face covered with the first grounding part ST1 in a case in which the mounting stand 12 is grounded using the third connection mode. This similarly applies also to a ratio of the second face covered with the second grounding part ST2. In consideration of these, it can be understood that the larger the area of the first face covered with the first grounding part ST1, the more reduction of the electric field strength at around 27.5 MHz inside the reverberation chamber 10 in a case in which electromagnetic waves are emitted from the antenna 11 tends to be suppressed. However, by comparing the frequency spectra illustrated in FIG. 12, it can be also understood that, when the ratio of the first face covered with the first grounding part ST1 exceeds 50%, the effect of suppressing the reduction of the electric field strength at around 27.5 MHz becomes small.

For simplification of the description, although description using drawings will be omitted, for example, in a case in which the first grounding part ST1 is connected to the first side 121 to cover the first face with a certain ratio, an effect that can be acquired for the reduction of the electric field strength by covering the first face with a plurality of first grounding members ST10 with this ratio is approximately the same as an effect that can be acquired for the above-described reduction of the electric field strength by covering the first face with the one first grounding member ST10 with this ratio. This similarly applies also to the second face. For this reason, in a case in which the mounting stand 12 is grounded using the first connection mode, the first face may be covered with a plurality of first grounding members. In such a case, the second face may be covered with a plurality of second grounding members. In any of such cases, the frequency spectrum of the first electric field strength is approximately the same as the frequency spectrum of the first electric field strength illustrated in FIG. 12. Such facts are similar also in a case in which the mounting stand 12 is grounded using the second connection mode and a case in which the mounting stand 12 is grounded using the third connection mode.

Next, FIG. 13 illustrates an example of a table comparing an analysis result of the reference electric field strength with analysis results of the fourth electric field strength to the sixth electric field strength.

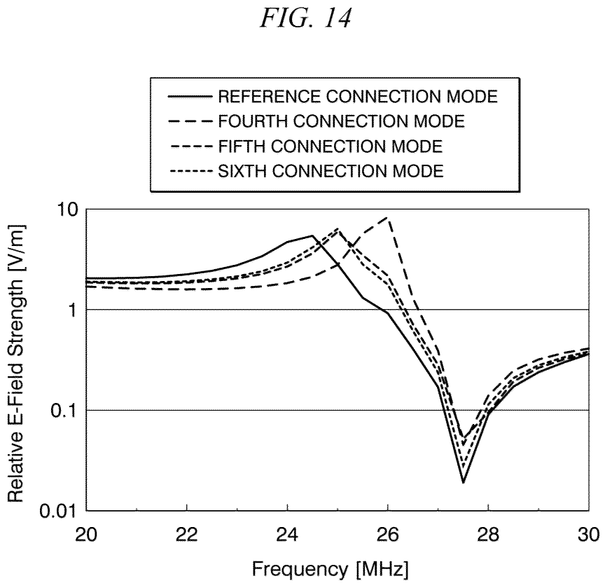

FIG. 13 illustrates a table representing an example of an analysis result of each of the reference electric field strength, the fourth electric field strength, the fifth electric field strength, and the sixth electric field strength. The frequency band of the frequency spectrum illustrated in FIG. 13 is also 20 MHz to 30 MHz, and the interval between frequencies is also 0.5 MHz. FIG. 14 is a diagram illustrating an example of graphs in which the frequency spectrums illustrated in FIG. 13 are plotted.

As illustrated in FIG. 14, all the fourth electric field strength to the sixth electric field strength decrease at around 27.5 MHz. However, all the fourth electric field strength to the sixth electric field strength are stronger than the reference electric field strength at 27.5 MHz. In other words, this represents that each of the fourth connection mode to the sixth connection mode can suppress a decrease in the electric field strength near the center of the mounting surface of the mounting stand 12 compared to the reference connection mode. The fifth electric field strength at 27.5 MHz is stronger than the fourth electric field strength at 27.5 MHz. In addition, the fourth electric field strength at 27.5 MHz is stronger than the sixth electric field strength at 27.5 MHz. A ratio of the first face covered with the first grounding part ST1 in a case in which the mounting stand 12 is grounded using the fourth connection mode is higher than a ratio of the first face covered with the first grounding part ST1 in a case in which the mounting stand 12 is grounded using the fifth connection mode. This similarly applies also to a ratio of the second face covered with the second grounding part ST2. A ratio of the first face covered with the first grounding part ST1 in a case in which the mounting stand 12 is grounded using the fifth connection mode is the same as a ratio of the first face covered with the first grounding part ST1 in a case in which the mounting stand 12 is grounded using the sixth connection mode. This similarly applies also to a ratio of the second face covered with the second grounding part ST2. However, although each of the first grounding members of the first grounding part ST1 faces one of the second grounding members of the second grounding part ST2 without overlapping in the fifth connection mode, each of the first grounding members of the first grounding part ST1 does not face any one of the second grounding members of the second grounding part ST2 in the sixth connection mode. In consideration of these, inside the reverberation chamber 10 in a case in which electromagnetic waves are emitted from the antenna 11, although the first grounding members ST10 and the second grounding members ST20 are separated from each other, it can be understood that the more the reduction of the electric field strength at around 27.5 MHz tends to be suppressed the larger the area of the first area covered with the first grounding part ST1. However, by comparing the frequency spectra illustrated in FIG. 12, it can be understood that, in a case in which the first grounding member ST10 and the second grounding member ST20 do not face each other, the effect of suppressing the reduction of the electric field strength at 27.5 MHz becomes small.

Next, FIG. 15 illustrates an example of a table comparing an analysis result of the reference electric field strength with each of analysis results of the seventh electric field strength and the eighth electric field strength.

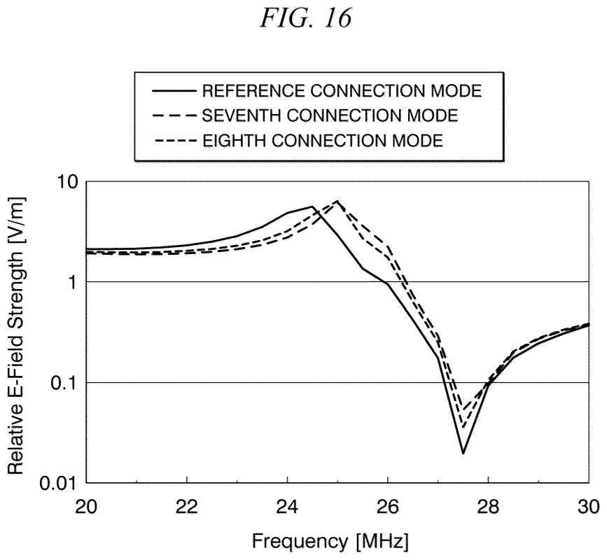

FIG. 15 illustrates a table representing an example of the analysis result of each of the reference electric field strength, the seventh electric field strength, and the eighth electric field strength. The frequency band of the frequency spectrum illustrated in FIG. 15 is also 20 MHz to 30 MHz, and the interval between frequencies is also 0.5 MHz. FIG. 16 illustrates an example of graphs in which the frequency spectra illustrated in FIG. 15 are plotted.

As illustrated in FIG. 16, both the seventh electric field strength and the eighth electric field strength decrease at around 27.5 MHz. However, both the seventh electric field strength and the eighth electric field strength are stronger than the reference electric field strength at 27.5 MHz. In other words, this represents that each of the seventh connection mode and the eighth connection mode can suppress a decrease in the electric field strength near the center of the mounting surface of the mounting stand 12 compared to the reference connection mode. The seventh electric field strength at 27.5 MHz is stronger than the eighth electric field strength at 27.5 MHz. In the eighth connection mode, different from the seventh connection mode, in a case in which the mounting stand 12 is seen in the negative direction of the Z axis, the first grounding part ST1 is located between a center line located at the center of the first side 121 and the second side 122 among virtual straight lines parallel to the first side 121 and the second side 122 and the first side 121 and does not overlap the first side 121. In addition, in the eighth connection mode, different from the seventh connection mode, in a case in which the mounting stand 12 is seen in the negative direction of the Z axis, the second grounding part ST2 is located between the center line and the second side 122 and does not overlap the second side 122. In consideration of these, inside the reverberation chamber 10 in a case in which electromagnetic waves are emitted from the antenna 11,, it can be understood that as each of the first grounding part ST1 and the second grounding part ST2 is connected to the mounting stand 12 by approaching the center line more, the effect of the reduction of the electric field strength at 27.5 MHz tends to become smaller as reduction of the electric field strength at around 27.5 MHz.

For simplification of the description, although description using drawings will be omitted, in a case in which the mounting stand 12 is seen in the first direction, when the shortest distance between the center line and the first side 121 is set as 1, it is preferable that the shortest distance from the center line to the first grounding part ST1 be a distance included in the range of 0.6 or more and less than 1, and, when the shortest distance between the center line and the second side 122 is set as 1, it is preferable that the shortest distance from the center line to the second grounding part ST2 be a distance included in this range. The reason for this is that, according to the analysis results, in a case in which these two shortest distances are in this range, it can be judged that the electric field strength at around 27.5 MHz is sufficiently stronger than the reference electric field strength at 27.5 MHz.

As described above, the electromagnetic wave testing device 1 according to the embodiment includes a reverberation chamber 10, an antenna 11 that is installed inside the reverberation chamber 10 and emits electromagnetic waves of frequencies below the first resonant frequency, a mounting stand 12, a first grounding part ST1, and a second grounding part ST2. In accordance with this, compared to a case in which the second grounding part ST2 is not included, the electromagnetic wave testing device 1 can improve the uniformity of the electric field strength on the grounded mounting stand 12 made of metal in a case in which a radiation immunity test using a low frequency band is conducted inside the reverberation chamber 10.

In addition, the items described above may be combined in any way.

### Supplementary Note

[1]

An electromagnetic wave testing device including: a reverberation chamber; an antenna installed inside the reverberation chamber and emitting electromagnetic waves of frequencies below a resonant frequency of the reverberation chamber; a mounting stand of a flat plate shape having a mounting surface, which is a face including a first side and a second side facing the first side, made of a conductor on which the test object is placed; a first grounding part electrically connecting an object having a ground electric potential and the first side to each other; and a second grounding part electrically connecting the object and the second side to each other.

[2]

The electromagnetic wave testing device described in [1], in which a shape of the mounting stand in a case in which the mounting stand is seen in a direction toward a floor face of the reverberation chamber among directions orthogonal to the mounting surface is a rectangular shape having the first side and the second side as long sides.

[3]

The electromagnetic wave testing device described in [1] or [2], in which the object is a floor face of the reverberation chamber.

[4]

The electromagnetic wave testing device described in [1] or [2], in which the object is a side wall face of the reverberation chamber.

[5]

The electromagnetic wave testing device described in any one of [1] to [4], in which the first grounding part includes a plurality of first grounding members electrically connecting the object and the first side to each other, and the second grounding part includes a plurality of second grounding members electrically connecting the object and the second side to each other.

[6]

The electromagnetic wave testing device described in [5], in which the number of the plurality of second grounding members is the same as the number of the plurality of first grounding members, and each of the plurality of first grounding members faces one of the plurality of second grounding members without overlapping in a direction parallel to the mounting surface among directions orthogonal to the first side and the second side.

[7]

The electromagnetic wave testing device described in any one of [1] to [4], in which the first grounding part includes one first grounding member that electrically connects the object and the first side to each other, and the second grounding part includes one second grounding member that electrically connects the object and the second side to each other.

[8]

The electromagnetic wave testing device described in any one of [1] to [7], in which a direction toward a floor face of the reverberation chamber among directions orthogonal to the mounting surface is set as a first direction, a virtual face having a rectangular shape having an area in which the first side is projected onto the floor face in the first direction among areas on the floor face and the first side as two sides facing each other is set as a first face, a direction from the first side toward the second side among directions orthogonal to the first face is set as a second direction, and a ratio of an area of the first grounding part to an area of the first face in a case in which the first face is seen in the second direction is 25% or more.

[9]

The electromagnetic wave testing device described in any one of [1] to [8], in which, in a case in which the mounting stand is seen in a direction toward a floor face of the reverberation chamber among directions orthogonal to the mounting surface, the first grounding part is located between a center line located at a center between the first side and the second side among virtual straight lines parallel to the first side and the second side and the first side and does not overlap the first side, and, in a case in which the mounting stand is seen in a direction toward the floor face of the reverberation chamber among directions orthogonal to the mounting surface, the second grounding part is located between the center line and the second side and does not overlap the second side.

[10]

The electromagnetic wave testing device described in [9], in which, in a case in which the mounting stand is seen in a direction toward the floor face of the reverberation chamber among directions orthogonal to the mounting surface, when a shortest distance between the center line and the first side is set as 1, a shortest distance from the center line to the first grounding part is a distance included in a range of 0.6 or more and less than 1, and, in a case in which the mounting stand is seen in a direction toward the floor face of the reverberation chamber among directions orthogonal to the mounting surface, when a shortest distance between the center line and the second side is set as 1, a shortest distance from the center line to the second grounding part is a distance included in a range of 0.6 or more and less than 1.

[11]

An electromagnetic wave testing device including: a reverberation chamber; a mounting stand of a flat plate shape having a mounting surface, which is a face including a first side and a second side facing the first side, made of a conductor on which a test object is placed; a first grounding part electrically connecting an object having a ground electric potential and the first side to each other; and a second grounding part electrically connecting the object and the second side to each other, in which an antenna emitting electromagnetic waves of frequencies below a resonant frequency of the reverberation chamber is installed in the reverberation chamber.

[12]

An electromagnetic wave testing method using an electromagnetic wave testing device including: a reverberation chamber; an antenna installed inside the reverberation chamber and emitting electromagnetic waves of frequencies below a resonant frequency of the reverberation chamber; and a mounting stand of a flat plate shape having a mounting surface, which is a face including a first side and a second side facing the first side, made of a conductor on which a test object is placed, the electromagnetic wave testing method including: electrically connecting an object having a ground electric potential and the first side to each other using a first grounding part; and electrically connecting the object and the second side to each other using a second grounding part.

While preferred embodiments of the present invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

1 Electromagnetic wave testing device
2 Information processing device
10 Reverberation chamber
11 Antenna
12 Mounting stand
13 Electromagnetic stirrer
121 First side
122 Second side
ST1 First grounding part
ST2 Second grounding part
ST10, ST11, ST12, ST13, ST14, ST15, ST16, ST17, ST18 First grounding member
ST20, ST21, ST22, ST23, ST24, ST25, ST26, ST27, ST28 Second grounding member
TC Three-dimensional coordinate system
TM Test object

What is claimed is:

1. An electromagnetic wave testing device comprising:
a reverberation chamber;
an antenna installed inside the reverberation chamber and emitting electromagnetic waves of frequencies below a resonant frequency of the reverberation chamber;
a mounting stand of a flat plate shape having a mounting surface, which is a face including a first side and a second side facing the first side, made of a conductor on which the test object is placed;
a first grounding part electrically connecting an object having a ground electric potential and the first side to each other; and
a second grounding part electrically connecting the object and the second side to each other.

2. The electromagnetic wave testing device according to claim 1, wherein a shape of the mounting stand in a case in which the mounting stand is seen in a direction toward a floor face of the reverberation chamber among directions orthogonal to the mounting surface is a rectangular shape having the first side and the second side as long sides.

3. The electromagnetic wave testing device according to claim 1, wherein the object is a floor face of the reverberation chamber.

4. The electromagnetic wave testing device according to claim 1, wherein the object is a side wall face of the reverberation chamber.

5. The electromagnetic wave testing device according to claim 1,
wherein the first grounding part includes a plurality of first grounding members electrically connecting the object and the first side to each other, and
the second grounding part includes a plurality of second grounding members electrically connecting the object and the second side to each other.

6. The electromagnetic wave testing device according to claim 5,
wherein the number of the plurality of second grounding members is the same as the number of the plurality of first grounding members, and
each of the plurality of first grounding members faces one of the plurality of second grounding members without overlapping in a direction parallel to the mounting surface among directions orthogonal to the first side and the second side.

7. The electromagnetic wave testing device according to claim 1,
wherein the first grounding part includes one first grounding member that electrically connects the object and the first side to each other, and
the second grounding part includes one second grounding member that electrically connects the object and the second side to each other.

8. The electromagnetic wave testing device according to claim 1,
wherein a direction toward a floor face of the reverberation chamber among directions orthogonal to the mounting surface is set as a first direction,
a virtual face having a rectangular shape having an area in which the first side is projected onto the floor face in the first direction among areas on the floor face and the first side as two sides facing each other is set as a first face,
wherein a direction from the first side toward the second side among directions orthogonal to the first face is set as a second direction, and
a ratio of an area of the first grounding part to an area of the first face in a case in which the first face is seen in the second direction is 25% or more.

9. The electromagnetic wave testing device according to claim 1,
wherein, in a case in which the mounting stand is seen in a direction toward a floor face of the reverberation chamber among directions orthogonal to the mounting surface, the first grounding part is located between a center line located at a center between the first side and the second side among virtual straight lines parallel to the first side and the second side and the first side and does not overlap the first side, and
in a case in which the mounting stand is seen in a direction toward the floor face of the reverberation chamber among directions orthogonal to the mounting surface, the second grounding part is located between the center line and the second side and does not overlap the second side.

10. The electromagnetic wave testing device according to claim 9,
wherein, in a case in which the mounting stand is seen in a direction toward the floor face of the reverberation chamber among directions orthogonal to the mounting surface, when a shortest distance between the center line and the first side is set as 1, a shortest distance from the center line to the first grounding part is a distance included in a range of 0.6 or more and less than 1, and
in a case in which the mounting stand is seen in a direction toward the floor face of the reverberation chamber among directions orthogonal to the mounting surface, when a shortest distance between the center line and the second side is set as 1, a shortest distance from the center line to the second grounding part is a distance included in a range of 0.6 or more and less than 1.

11. An electromagnetic wave testing device comprising:
a reverberation chamber;
a mounting stand of a flat plate shape having a mounting surface, which is a face including a first side and a second side facing the first side, made of a conductor on which a test object is placed;
a first grounding part electrically connecting an object having a ground electric potential and the first side to each other; and
a second grounding part electrically connecting the object and the second side to each other,
wherein an antenna emitting electromagnetic waves of frequencies below a resonant frequency of the reverberation chamber is installed in the reverberation chamber.

12. An electromagnetic wave testing method using an electromagnetic wave testing device including:
a reverberation chamber;
an antenna installed inside the reverberation chamber and emitting electromagnetic waves of frequencies below a resonant frequency of the reverberation chamber; and
a mounting stand of a flat plate shape having a mounting surface, which is a face including a first side and a second side facing the first side, made of a conductor on which a test object is placed,
the electromagnetic wave testing method comprising:
electrically connecting an object having a ground electric potential and the first side to each other using a first grounding part; and
electrically connecting the object and the second side to each other using a second grounding part.
